(19) United States
(12) Patent Application Publication
(10) Pub. No.: US 2007/0004114 A1
(43) Pub. Date: Jan. 4, 2007

(54) Sacrificial capping layer for transistor performance enhancement

(76) Inventors: Seok-Hee Lee, Portland, OR (US); Sanjay Natarajan, Portland, OR (US); Ramune Nagisetty, Portland, OR (US); Sunit Tyagi, Portland, OR (US); Guiseppe Curello, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/174,230

(22) Filed: Jun. 30, 2005

(51) Int. Cl. H01L 21/8234

(52) U.S. Cl. 438/197

(57) ABSTRACT

A process for fabricating an n channel transistor, which results in electron mobility improvement in the channel, is described. Sacrificial capping layers comprising an oxide and nitride layer are conformally formed over a polysilicon gate after source and drain implantation, and remain in place during annealing.

### BACKGROUND OF THE INVENTION

The invention relates to field of MOS transistors.

### PRIOR ART

It is known that for metal-oxide-semiconductor (MOS) field-effect transistors (FEIs), residual channel tensile stress in the n channel (NMOS) transistors improves carrier mobility and consequently, improves transistor performance. The tensile stress while improving NMOS transistors, degrades the performance of a p channel(PMOS) transistor. Therefore, a balance must be achieved in providing such stress.

One technique for providing channel stress employs a silicon nitride etch stop layer. This technique, particularly at smaller gate geometries, does not work well due to the limited volume of the nitride layer between the gates. In addition, this technique often requires an additional implant to recover the PMOS transistor performance.

Another process for increasing carrier mobility in NMOS transistors employs a relatively thick chemical vapor deposited (CVD) oxide capping layer. The layer is formed prior to source-drain activation anneal. This process does not work well at small geometries for several reasons. For one, the needed oxide thickness is difficult to remove without removal of oxide used for isolation between the transistors. Additionally, PMOS transistor degradation occurs due to the loss of the boron dopant from the PMOS source and drain regions.

### BRIEF DESCRIPTION OF THE DRAWINGS

FIG. 1 is a cross-sectional, elevation view of a polysilicon gate shown during ion implantation used to form tip implant regions.

FIG. 2 illustrates the structure of FIG. 1 following the formation of sidewall spacers on the gate.

FIG. 3 illustrates the structure of FIG. 2 during ion implantation used to form the source and drain regions.

FIG. 4 illustrates the substrate of FIG. 3 following the formation of an oxide layer and nitride layer over the substrate and during annealing.

FIG. 5 illustrates the structure of FIG. 4 following the removal of the nitride layer and a portion of the oxide layer.

FIG. 6 illustrates the substrate of FIG. 5 during ion bombardment used to prepare the silicon surfaces for silicide formation.

FIG. 7 illustrates the structure of FIG. 6 following the formation of a silicide.

FIG. 8 is a scanning electron microscope view of a gate and source and drain regions following the ion bombardment of FIG. 6. This is used to illustrate the use of the oxide spacer.

FIG. 9 is a graph illustrating the increase in performance attributable to the processing of the present invention.

FIG. 10 is a graph which illustrates the increase in electron mobility attributable to the present invention.

FIG. 11A is a plan view illustrating temperature distribution in the substrate during annealing without the present invention.

FIG. 11B illustrates the temperature distribution in the substrate during annealing when the bi-layer of the present invention is employed.

### DETAILED DESCRIPTION

A method for fabricating a MOS field-effect transistor, particularly an n channel transistor, is described. In the following description, numerous specific details are set forth, such as specific temperature ranges. It will be apparent to one skilled in the art that the present invention may be practiced without these specific details. In other instances, well-known processing is not described in detail in order not to unnecessarily obscure the present invention.

As will be seen, tensile stress is provided in an n channel transistor during re-crystallization. This occurs when annealing with oxide and nitride layers in place. Less re-crystallization occurs in the p channel transistors since the boron causes less damage. Consequently, more tensile stress remains in the n channel transistors than the p channel transistors.

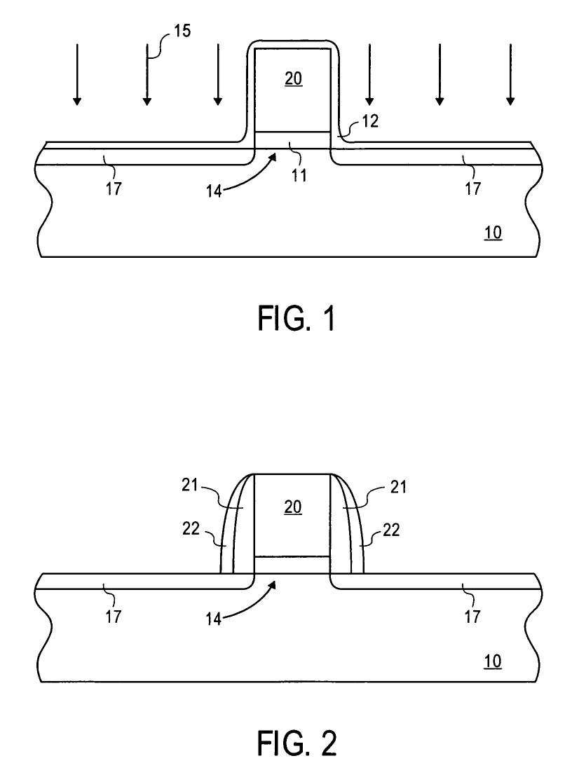

Referring now to FIG. 1, a semiconductor substrate 10 is illustrated such as a monocrystalline silicon substrate. A single gate for a field-effect transistor, more specifically a polysilicon gate 20, is illustrated. The gate 20 is insulated from the substrate 10 by an insulative layer, such as an oxide layer 11. A protective oxide 12 covers the substrate and gate. In the cross-sectional, elevation view of FIG. 1, ion implantation is illustrated by the arrows 15. For the n channel transistor described, implantation of phosphorous or arsenic or both is employed. This particular implantation of an n type dopant results in relatively lightly doped regions 17, with a channel region 14 disposed therebetween.

After removal of the oxide layer 12, sidewall spacers are formed on the sides of the polysilicon gate 20. As shown in FIG. 2, the gate structure comprises silicon nitride spacers 21 disposed on opposite sides of the gate 20, and additionally, oxide spacers 22. The spacers are formed using ordinary technology, well-known in the art. Often, only a single spacer, such as the nitride spacer 21, is used. In some processes however, a second oxide spacer is used primarily to enable an epitaxial growth for the p channel transistors.

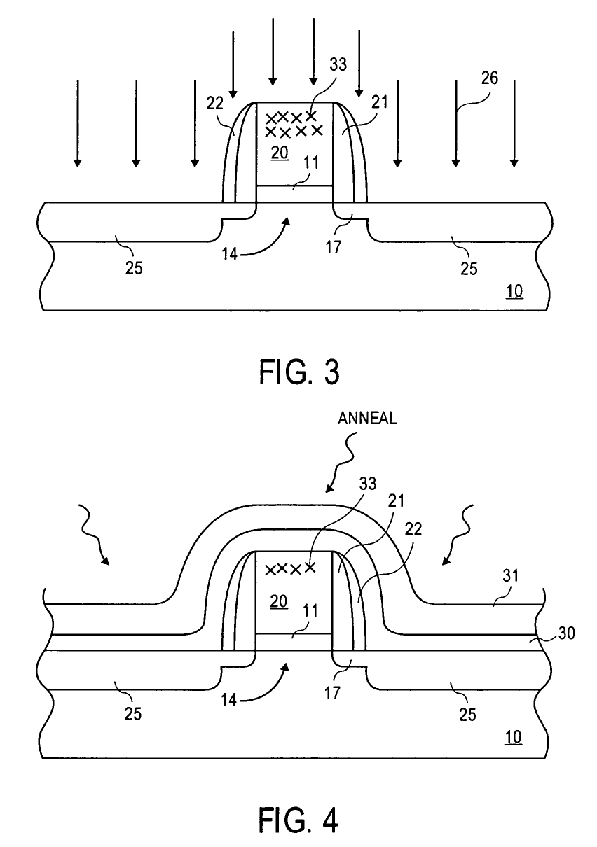

Now as shown in FIG. 3, the source and drain regions are formed by the implantation of an n type dopant such as either or both, phosphorous and arsenic. The sidewall spacers 21 and 22 assure that the implanted regions 25 are outside the channel 14 and that only the tip implant regions 17 extends up to the edge of polysilicon gate 20. Note that in FIG. 3, the source and drain regions 25 appear as fully formed regions, even though at this point in the processing, the dopant has not been activated nor is it fully diffused.

Following the ion implantation of the n type dopant and before annealing, two layers are conformally formed over the substrate using, for instance, CVD. The first of these layers is the oxide layer 30 formed directly on the substrate and over the gate structure. This oxide layer may have a thickness, for example, between 100-500 Å. Then, a silicon nitride layer is deposited on the oxide layer 30. The nitride layer 31 may have a thickness between, for instance, 400-1,000 Å. This bi-layer (layers 30 and 31) remain in place during the annealing of the substrate used to activate the dopant in the source and drain regions and which repairs damage to the crystalline structures typically damaged during ion implantation.

In one embodiment, both layers 30 and 31 are deposited in a plasma enhanced CVD tool at approximately 400° C. Both layers are formed without using low frequency RF power in order to control the hydrogen content in the films and the density of the films. The films should be able to withstand stress placed on them during a subsequent annealing step, and in effect, are used to clamp the gate during annealing.

The annealing, as shown in FIG. 4, takes place at a temperature of 900° C. or greater, and more typically in the range of 900-1,200° C. Rapid thermal annealing is used and, for instance, the annealing can be done with a thermal spike, with other rapid thermal processing such as ultra-fast annealing or with laser flash annealing.

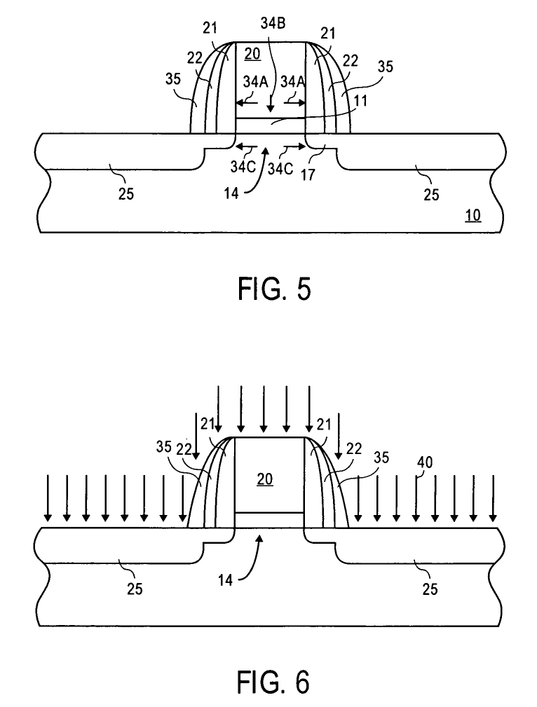

During ion implantation, as shown in FIG. 3, damage occurs to the monocrystalline silicon of the substrate 10, in addition to damage to the polysilicon of the gate 20. This damage is represented by the “Xs” 33 in FIGS. 3 and 4. During the annealing this damage is repaired as re-crystallization occurs. The re-crystallization proceeds upward into the amorphized regions 33. This causes a tensile stresses in the gate 20 since the gate is confined, or in effect, clamped in place by the layers 30 and 31. After removal of the layers 30 and 31, these stresses remain, as shown by the arrows 34A and 34B in FIG. 5. This stress occurs in the horizontal direction as shown by arrows 34A as well as in the downward direction (compression) as shown by arrow 34B. The stresses in the gate 20 provides a corresponding tension within the channel region 14 and this stress also remains after removal of the layers 30 and 31. Additionally, dislocations occur near the channel region 14 resulting in strain fields which induce tensile stress in the channel.

Following the annealing, the nitride layer 31 is removed and all of, or a portion of, the oxide layer 30 is also removed. The nitride capping layer may be removed with a conditioned hot phosphoric acid. This limits the oxide loss. The layer 30 serves as an etchant stop during the removal of the nitride. The oxide layer 30 may be removed with, for instance, an HF cleaning step or with plasma etching. In one embodiment, the oxide layer 30 is not entirely removed, rather additional sidewall spacers 35 formed from this layer remain as shown in FIG. 5. The purpose of these additional sidewall spacers 35 is discussed below.

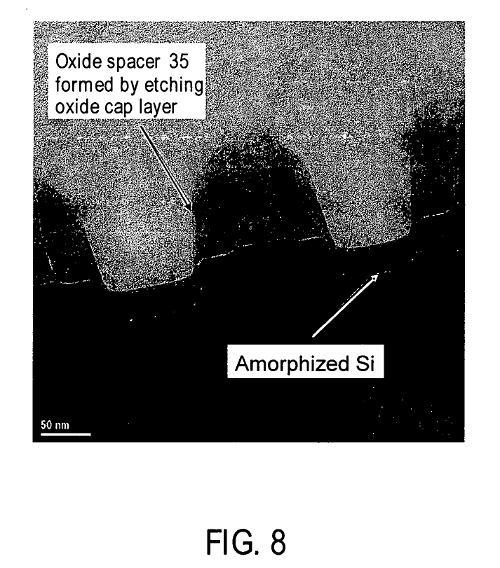

In one embodiment, a silicide or salicide is formed on exposed silicon following the removal of layer 30 and the partial removal of layer 11. Before this is done, the surface of the silicon is first prepared, and in effect, made amorphous by bombardment with ions as shown by the ion bombardment 40 of FIG. 6. This resultant structure is shown in FIG. 8, where the oxide spacers 35 are disposed adjacent the source and drain regions. The amorphized silicon in these regions is identified. Importantly, as is illustrated in both FIGS. 6 and 8, the oxide spacers 35 prevent damage to the source and drain regions immediately adjacent to the spacers 21 and 22. By moving the damaged silicon region away from the gate, parasitic resistance is reduced.

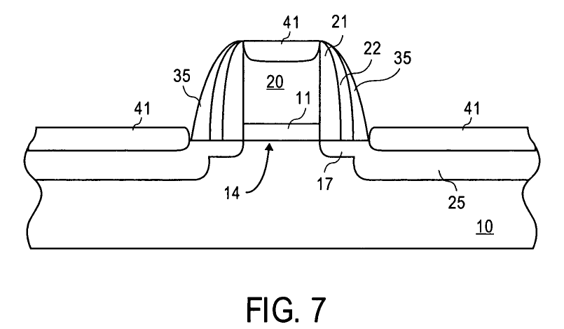

Now, a silicide is formed on the exposed silicon, and specifically, on the source and drain regions and the gate, as shown by the silicide 41 in FIG. 7.

Well-known processing may be used to complete the fabrication of an integrated circuit which includes the NMOS transistor of FIG. 7.

As mentioned earlier, tensile stress in the channels NMOS transistors improves mobility. This occurs because of the reduced effective mass, and the reduced phonon scattering. In contrast, the same tensile stress degrades the performance of PMOS transistors. The boron dopant used to form the source and drain regions, and to dope the gate in PMOS transistors, does not do as much damage to the crystalline structure as does the n type dopant. Consequently during annealing, there is less re-growth in the crystalline structure and less stress occurs in the polysilicon gates of the PMOS transistors. For this reason, the improved performance made in the NMOS transistors is not offset by the loss of performance in the PMOS transistors.

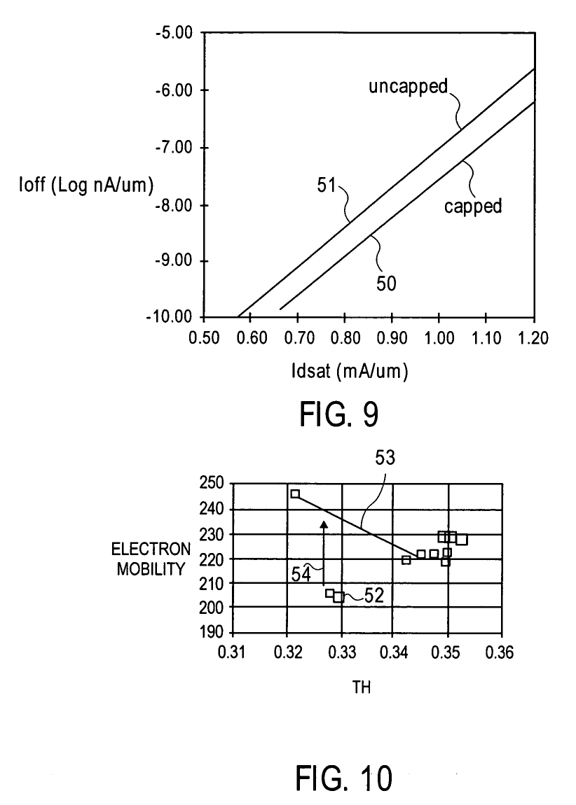

One measure of the improvement obtained with the described process in an NMOS transistor is shown in FIG. 9. Line 51 represents the off current density versus the saturation current density without the use of the capping layers 30 and 31 described above. Line 50, on the other hand, represents this performance when these layers are used. One way of looking at this, is that for a given drive current, the off current is lower when using the capping layers. Thus for a given drive current, less power is consumed. Looked at in another way, for a given amount of power, the drive current is increased. As shown in FIG. 9, a 7-8% gain is achievable by using the capping layers.

In FIG. 10, threshold voltage (TH) is plotted against electron mobility. The points 52 represent experimental data obtained from NMOS transistors fabricated without using the capping layers 30 and 31. Line 53 is plotted using measured data taken with transistors using the capping layer. As indicated by the arrow 54, there is approximately 15% mobility gain at a fixed threshold of about 0.33 volts for this data.

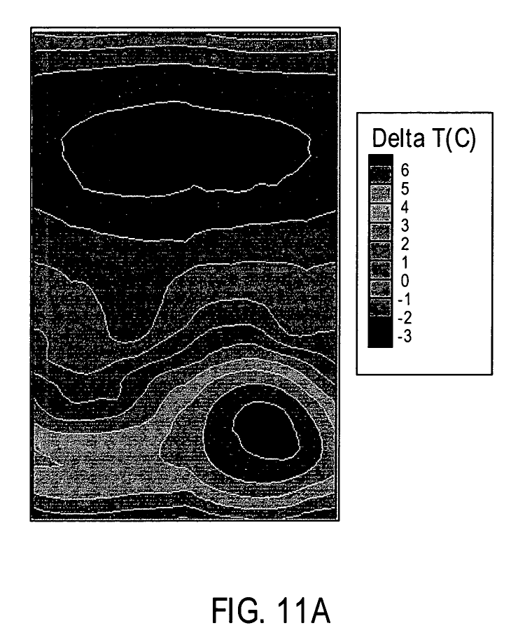

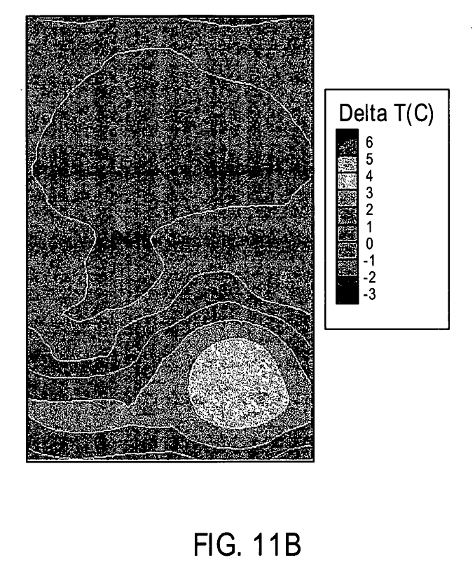

Finally, as shown in FIG. 11A and 11B, die temperature uniformity is improved during the source and drain annealing because of the capping layer. FIG. 11A shows the temperature distribution without the capping layers, and FIG. 11B shows the temperature distribution with the capping layers. As can be seen, there is more uniformity primarily due to the reflectivity of the nitride film. A substantial improvement in uniformity is obtained as can be readily seen by comparing FIGS. 11A and 11B.

Thus, a process for fabricating an NMOS transistor has been described which uses oxide and nitride layers to clamp a polysilicon gate during an annealing step. The result is tensile stress in the channel, which improves electron mobility in the n channel transistors.

What is claimed is:

1. A method of fabricating a transistor comprising:
forming a gate structure on a substrate;
doping the gate structure and substrate adjacent to the gate structure with a dopant;
depositing an oxide layer over the gate structure and substrate;
forming a nitride layer over the oxide layer; and
annealing the gate structure and substrate with the oxide layer and nitride layer in place.

2. The method of claim 1, wherein the doping comprises ion implantation of an n type dopant.

3. The method of claim 2, wherein the annealing comprises rapid thermal annealing.

4. The method of claim 2, wherein the gate structure includes a polysilicon gate.

5. The method of claim 4, wherein the gate structure includes spacers disposed on sides of the polysilicon gate.

6. The method of claim 5, including implanting an n type dopant into the substrate prior to the formation of the spacers.

7. The method of claim 6, including removing the nitride layer and at least a part of the oxide layer following the annealing.

8. The method of claim 1, including removing the nitride layer and a portion of the oxide layer, thereby leaving oxide spacers on sides of the gate structure.

9. The method of claim 8, including forming silicide on the substrate and exposed polysilicon of the gate structure, the silicide being displaced from the gate structure by the oxide spacers.

10. A method of fabricating an n-channel MOS transistor on a silicon substrate comprising:
capping a gate structure with an oxide and nitride layer; and
annealing the capped gate structure after implanting ions into the substrate.

11. The method of claim 10, wherein the gate structure includes a polysilicon gate and sidewall spacers formed on the polysilicon gate.

12. The method of claim 11, wherein the annealing is done with a spike thermal cycle having a maximum temperature within the range of 900-1,200° C.

13. The method of claim 12, wherein the oxide layer is between 100-500 Å thick, and the nitride layer is between 400-1,000 Å thick.

14. The method of claim 10, including the removing of the nitride layer and at least a portion of the oxide layer following the annealing.

15. The method of claim 14, including the formation of silicide on exposed regions of the substrate, the silicide being displaced from the gate structure by a portion of the oxide layer remaining on sides of the gate structure.

16. A method for increasing mobility in a n channel transistor comprising:
forming oxide and nitride capping layers over a polysilicon gate after the gate has been implanted with an n-type dopant; and
subjecting the capped gate to thermal annealing such that a channel region beneath the gate in a substrate is in tension.

17. The method defined by claim 16, wherein the polysilicon gate includes first sidewall spacers disposed along sides of the gate prior to the formation of the capping layer.

18. The method defined by claim 17, wherein source and drain regions are implanted in alignment with the first sidewall spacers when the gate is implanted with the n-type dopant.

19. The method defined by claim 16, including removal of the nitride layer and at least a portion of the oxide layer leaving oxide spacers on the sidewall spacers.

20. The method defined by claim 19, including the ion bombardment of the substrate adjacent to the gate, the ion bombardment being done such that the oxide spacers prevent the substrate below the oxide spacers from being damaged.

21. The method defined by claim 20, including the formation of a silicide on exposed silicon of the substrate.
